(19) United States
(12) Patent Application Publication
(10) Pub. No.: US 2024/0347370 A1
(43) Pub. Date: Oct. 17, 2024

(54) CARRIER DECHUCKING SYSTEM AND CARRIER DECHUCKING METHOD USING CARRIER DECHUCKING SYSTEM

(71) Applicant: SAMSUNG ELECTRONICS CO., LTD., Suwon-si (KR)

(72) Inventors: Dongjoon Lee, Suwon-si (KR); Kyoungran Kim, Suwon-si (KR); Kwanghyeon Jeong, Suwon-si (KR); Myeongock Ko, Suwon-si (KR); Jaeuk Sim, Suwon-si (KR); Seongbeom Lee, Suwon-si (KR); Daesung Jung, Suwon-si (KR)

(21) Appl. No.: 18/542,172

(22) Filed: Dec. 15, 2023

(30) Foreign Application Priority Data
Apr. 13, 2023 (KR) 10-2023-0048872

(51) Int. Cl. H01L 21/687; H01L 21/66; H05F 3/06

(52) U.S. Cl. CPC H01L 21/68742; H01L 22/14; H05F 3/06

(57) ABSTRACT

A carrier dechucking system includes a work carrier including a substrate having a first surface, an opposite second surface with a support film attached, and a ring frame surrounding the substrate. The work carrier is placed on a placement table having a support surface on which a lower surface of the support film is maintained, lifting pins configured to move the work carrier, an ionizer configured to eject ions to the lower surface, and a controller. The controller is configured to control the lifting pins to move the work carrier from the support surface to first and second levels, and to control the ionizer to remove static electricity charged on the support film from the support surface to the first level. At the first level, a surface voltage of the first surface of the substrate is lower than a surface voltage of the lower surface of the support film.

### CROSS-REFERENCE TO RELATED APPLICATION(S)

This application claims benefit of priority to Korean Patent Application No. 10-2023-0048872 filed on Apr. 13, 2023, in the Korean Intellectual Property Office, the disclosure of which is incorporated herein by reference in its entirety.

### BACKGROUND

In order to form a ball grid array (BGA) on one surface of a substrate, a solder ball attachment process for disposing a flux and solder balls on ball pads of the substrate and a reflow process for melting and bonding the solder balls by applying an external heat source may be performed. When the substrate is separated from a support surface of a placement table to be subjected to the reflow process after the solder ball attachment process is completed, the solder balls, temporarily attached to the substrate, may deviate from aligned positions thereof due to peeling electrification.

### SUMMARY

An aspect of the present inventive concept provides a carrier dechucking system and a carrier dechucking method using the same to restrict a decrease in reliability caused by static electricity, when a substrate to which solder balls are temporarily attached is separated from a placement table.

According to an aspect of the present inventive concept, there is provided a carrier dechucking system including a work carrier including a substrate having a first surface to which solder balls are attached and a second surface, opposite to the first surface, a support film attached to the second surface of the substrate, and a ring frame surrounding the substrate on an outer periphery of the support film, a placement table on which the work carrier is placed, the placement table having a support surface on which a lower surface of the support film is maintained, lifting pins configured to move the work carrier in a direction, perpendicular to the support surface of the placement table, at least one ionizer configured to eject ions to the lower surface of the support film, and a controller configured to control the lifting pins such that the work carrier is moved from the support surface to a first level and a second level in a stepwise manner, and to control the at least one ionizer such that static electricity charged on the support film is removed in a section from the support surface to the first level. The first level may be a position at which a first surface voltage of the first surface of the substrate is lower than a second surface voltage of the lower surface of the support film.

According to another aspect of the present inventive concept, there is provided a carrier dechucking system including a support film on which a substrate to which solder balls are attached is mounted, a placement table having a support surface on which the support film is maintained, lifting pins configured to move the support film in a direction, perpendicular to the support surface of the placement table, at least one ionizer configured to eject ions to the support film, and a controller configured to control the lifting pins such that the support film is lifted from the support surface to a first level and a second level in a stepwise manner, and to control the at least one ionizer to eject the ions after the support film is positioned on the first level.

According to another aspect of the present inventive concept, there is provided a carrier dechucking system including a support film on which a substrate to which solder balls are attached is mounted, a placement table having a support surface on which the support film is maintained, lifting pins configured to move the support film in a direction, perpendicular to the support surface of the placement table, at least one ionizer configured to eject ions to a lower surface of the support film through an ion ejection path, passing through an interior of the placement table and extending to the support surface, and a controller configured to control the lifting pins such that the support film is lifted from the support surface to a first level and a second level in a stepwise manner.

According to another aspect of the present inventive concept, there is provided a carrier dechucking method including maintaining a support film to which a substrate is attached on a support surface of a placement table, attaching solder balls to the substrate, moving, by lifting pins, the support film from the support surface to a first level, ejecting, by at least one ionizer, ions to a lower surface of the support film after the support film is positioned on the first level or while the support film is lifted to the first level, moving, by the lifting pins, the support film to a second level after ejection of the ions is terminated, and unloading the support film after the support film is positioned on the second level.

### BRIEF DESCRIPTION OF DRAWINGS

The above and other aspects, features, and advantages of the present inventive concept will be more clearly understood from the following detailed description, taken in conjunction with the accompanying drawings.

FIG. 1 is a perspective view of a carrier support device according to some implementations.

FIG. 2A is a flowchart illustrating a dechucking process according to a carrier dechucking system according to some implementations, and FIGS. 2B to 2D are diagrams sequentially illustrating a carrier dechucking process according to some implementations.

FIG. 3 is a schematic diagram illustrating a carrier dechucking system according to some implementations.

FIG. 4A is a flowchart illustrating a dechucking process performed by a carrier dechucking system according to some implementations, and FIGS. 4B to 4E are diagrams sequentially illustrating a carrier dechucking process according to some implementations.

FIG. 5A is a graph illustrating a surface voltage of a substrate with respect to a separation distance between a work carrier and a placement table according to some implementations, and FIG. 5B is a graph illustrating a difference in surface voltages of a substrate depending on whether an ionizer is operated when a work carrier is lifted in a stepwise manner according to some implementations.

FIG. 6 is a schematic diagram illustrating a carrier dechucking system according to some implementations.

FIG. 7A is a schematic diagram illustrating a carrier dechucking system according to some implementations, and FIG. 7B is a graph illustrating a difference in surface voltages of a substrate depending on whether lifting pins are grounded according to some implementations.

FIG. 8 is a schematic diagram illustrating a carrier dechucking system according to some implementations.

FIG. 9A is a flowchart illustrating a dechucking process performed by a carrier dechucking system according to some implementations, and FIGS. 9B to 9D are diagrams sequentially illustrating a carrier dechucking process according to some implementations.

FIG. 10A is a graph illustrating a surface voltage of a substrate with respect to a flow rate of an ionizer according to some implementations, and FIGS. 10B and 10C are graphs illustrating a difference in surface voltages of a substrate according to a difference in a first level, when a work carrier is lifted in a stepwise manner under the condition that an ionizer has the same flow rate, according to some implementations.

### DETAILED DESCRIPTION

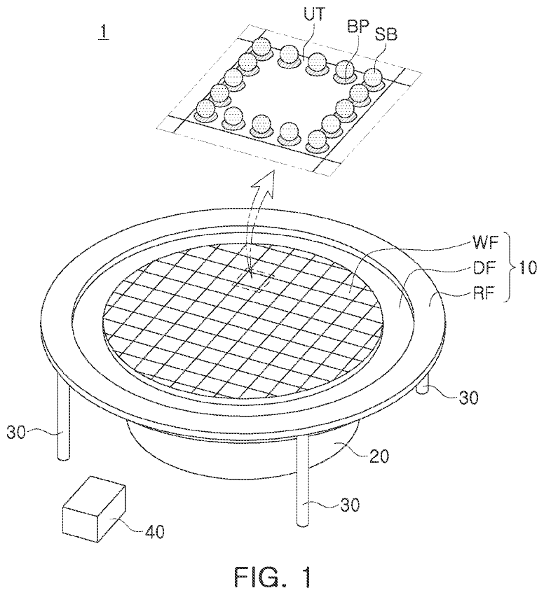

FIG. 1 is a perspective view of a carrier support device 1 according to some implementations.

Referring to FIG. 1, the carrier support device 1 may include a placement table 20, lifting pins 30, and an ionizer 40.

The placement table 20 may be a chuck table adsorbing and fixing a work carrier 10. The placement table 20 may be a vacuum chuck to which vacuum pressure is applied to a support surface on which the work carrier 10 is maintained. A support surface of the placement table 20 may be in contact with the work carrier 10. The work carrier 10 may include a substrate WF, a support film DF, and a ring frame RF. The substrate WF may include a plurality of units UT vertically and horizontally adjacent to each other. The plurality of units UT may be unit dies or unit packages. For example, the substrate WF may include ball pads BP on a main surface, opposite to the support film DF, and solder balls SB are disposed on ball pads BP. The support film DF may support the substrate WF in a subsequent process such as a reflow process or a dicing process. The support film DF may be, for example, a dicing film.

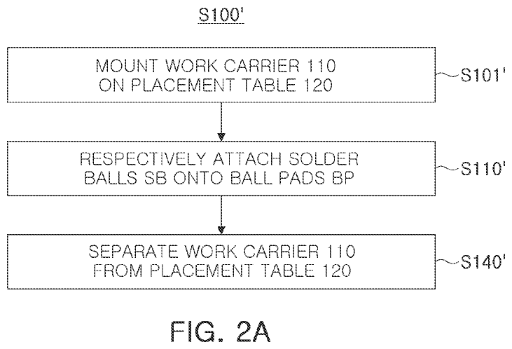

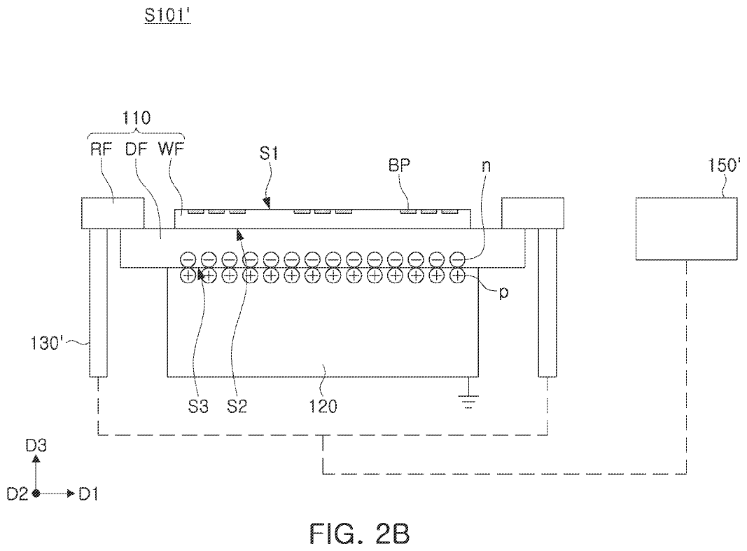

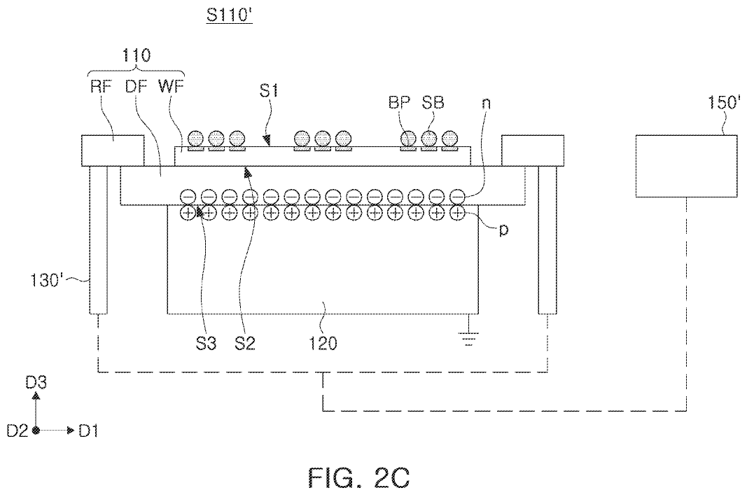

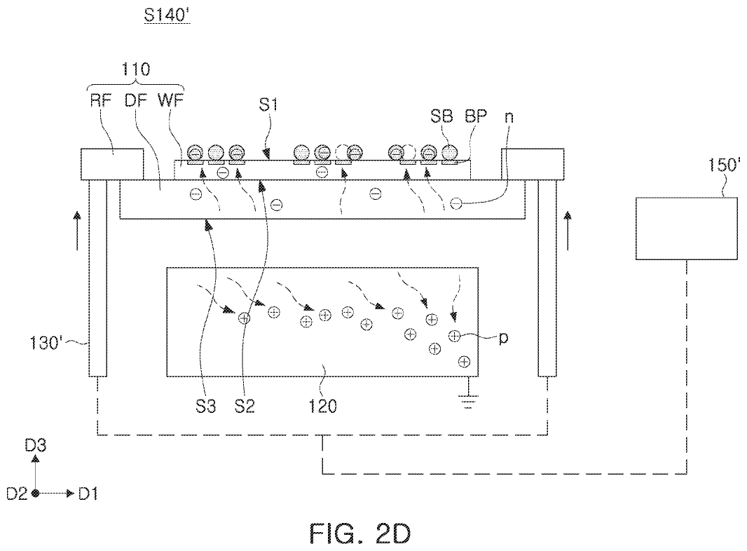

The support film DF may include a polymer material. When the support film DF is in contact with the placement table 20, the support film DF may be positively or negatively charged, depending on a charging order of a material (for example, metal) included in the placement table 20. When the support film DF is separated from the placement table 20 after a process of attaching the solder balls SB is completed, charges, generated by peeling electrification, may induce repulsive force between the solder balls SB, resulting in ball shift (see FIGS. 2A to 2D). A carrier dechucking system according to some implementations may remove charges charged on the support film DF while maintaining attractive force between charges charged on the support film DF and the placement table 20, thereby restricting a shift of the solder balls SB caused by peeling electrification (static electricity).

The lifting pins 30 may be disposed around the placement table 20. The lifting pins 30 may be configured to push the work carrier 10 in an upward direction. For example, the lifting pins 30 may press the ring frame RF of the work carrier 10 to separate the entire work carrier 10 from the placement table 20. The lifting pins 30 may lift the work carrier 10 using a driving means such as a linear actuator. The linear actuator may include, for example, a piezoelectric actuator, but the present inventive concept is not limited thereto. In some implementations, the linear actuator may include a voice coil actuator (VCA) or the like.

The ionizer 40 may be configured to eject ionized air between the placement table 20 and the work carrier 10. The ionizer 40 may eject ions (a positive ion and/or a negative ion) generated therein to the outside through an air outlet. The ionizer 40 may include a fan blowing out ions by blowing in outside air, but the present inventive concept is not limited thereto. For example, the ionizer 40 may eject ions together with air supplied from an air supply source.

FIG. 2A is a flowchart illustrating a dechucking process according to a carrier dechucking system S100′ according to some implementations, and FIGS. 2B to 2D are diagrams sequentially illustrating a carrier dechucking process according to some implementations.

Referring to FIGS. 2A and 2B, first, a work carrier 110 may be mounted on a placement table 20 (S101′). The work carrier 110 may be adsorbed and fixed by vacuum pressure applied to a support surface of the placement table 120. A support film DF to which a substrate WF is attached may be maintained on the support surface of the placement table 120. The work carrier 110 may be in contact with the placement table 120 through a lower surface S3 of the support film DF. The substrate WF may have a first surface S1 on which ball pads BP are disposed and a second surface S2 in contact with the support film DF. The support film DF and the placement table 120 may be charged at contact surfaces, respectively. For example, when the support film DF includes polyethylene and the placement table 120 includes aluminum, the support film DF may be charged with a negative charge (n) and the placement table 120 may be charged with a positive charge (P). However, the support film DF and the placement table 120 may be charged as opposed to the above-described charging depending on a charging order of materials included therein. The lifting pins 130′ may be in contact with the ring frame RF of the work carrier 110, but the present inventive concept is not limited thereto. The lifting pins 130′ may be separated from the work carrier 110 and may be in standby. The lifting pins 130′ may lift the work carrier 110 in a vertical direction D3, depending on a driving signal of a controller 150′.

Referring to FIGS. 2A and 2C, solder balls SB may be respectively attached to ball pads BP (S110′). The solder balls SB may include tin (Sn), indium (In), bismuth (Bi), antimony (Sb), copper (Cu), silver (Ag), zinc (Zn), lead (Pb), or an alloy (for example, Sn—Ag—Cu) containing the above-described elements. The solder balls SB may be attached to positions aligned with the ball pads BP. The alignment of the solder balls SB may be maintained by a flux on the ball pads BP.

Referring to FIGS. 2A and 2D, the work carrier 110 may be separated from the placement table 20 (S140′). The work carrier 110 may be lifted to an unloading position by the lifting pins 130′. The unloading position may refer to a level at which the work carrier 110 may be stably picked up by a robot arm or the like in order to provide the work carrier 110 to a subsequent process (for example, a reflow process). As the support film DF and the placement table 120 are separated from each other, attractive force between the negative charge (n) charged on the support film DF and the positive charge (p) charged on the placement table 20 may be reduced. The positive charge (p) charged on the placement table 20 may be removed through a ground path. The negative charge (n) charged on the support film DF may move to a first surface S1 of the substrate WF to charge the solder balls SB. As a result, repulsive force may act between the adjacent solder balls SB, such that the solder balls SB may deviate from the aligned positions.

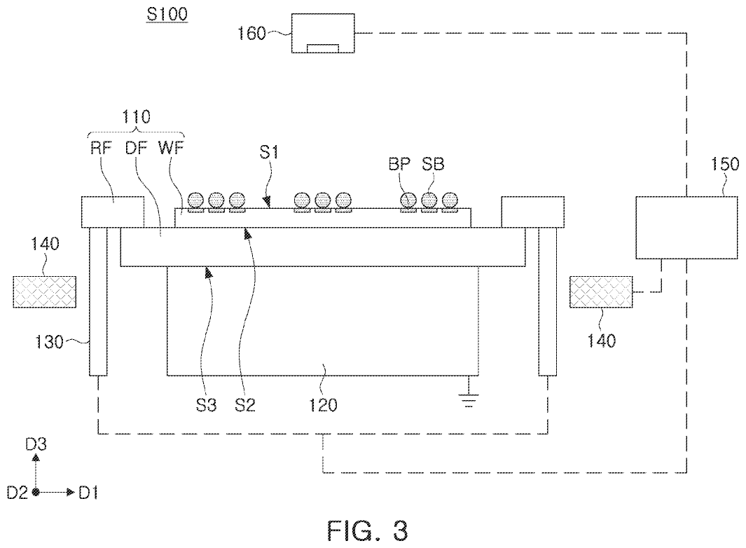

FIG. 3 is a schematic diagram illustrating a carrier dechucking system S100 according to some implementations.

Referring to FIG. 3, the carrier dechucking system S100 according to some implementations may include a work carrier 110, a placement table 120, lifting pins 130, at least one ionizer 140, and a controller 150.

The work carrier 110 may include a substrate WF, a support film DF, and a ring frame RF. The substrate WF may have a first surface S1 to which solder balls SB are attached and a second surface S2 opposite to the first surface S1. That is, the work carrier 110 may include a substrate WF to which the solder balls SB are attached. The carrier dechucking system according to some implementations of the present inventive concept may remove charges charged on the support film DF while maintaining attractive force between charges charged on the support film DF and the placement table 120, thereby restricting a shift of the solder balls SB caused by peeling electrification (static electricity).

The support film DF may be attached to a second surface S2 of the substrate WF. The support film DF may be an adhesive film, for example, a dicing film provided in a sawing process of the substrate WF. The ring frame RF may be formed to surround the substrate WF on an outer periphery of the support film DF. The ring frame RF may be integrated with the support film DF to provide a pickup region for the work carrier 110. The form and material of the ring frame RF are not particularly limited.

The placement table 120 may be a chuck table on which the work carrier 110 is placed. The placement table 120 may have a support surface on which the lower surface S3 of the support film DF is maintained. The placement table 120 may be a vacuum chuck adsorbing and fixing the support film DF by applying vacuum pressure to the support surface. The placement table 120 may include a ground path for removing static electricity when the work carrier 110 is separated.

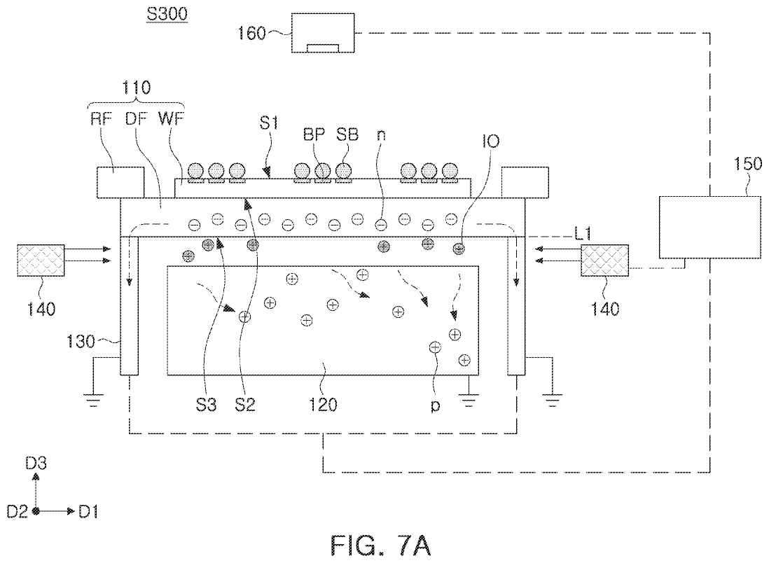

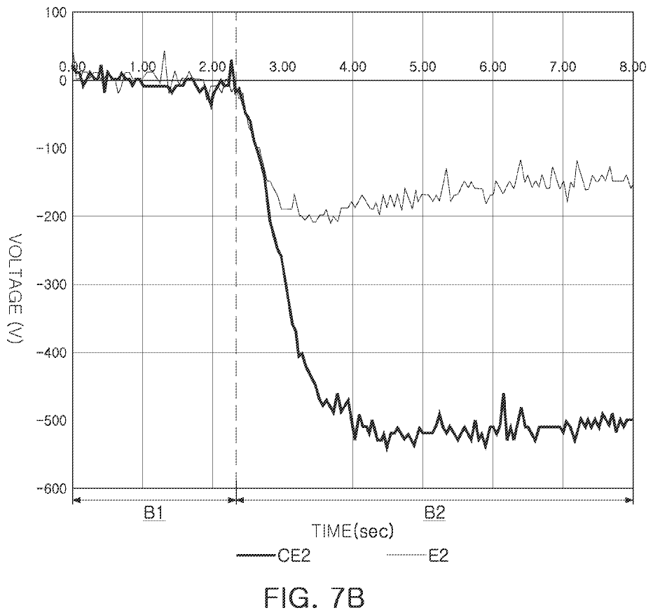

The lifting pins 130 may be configured to move the work carrier 110 in a direction D3, perpendicular to the support surface of the placement table 120. The lifting pins 130 may press a lower portion of the ring frame RF using a driving means such as an actuator. In some implementations, the lifting pins 130 may press the lower surface S3 of the support film DF (see FIG. 7A). In the carrier dechucking system according to some implementations, the lifting pins 130 may lift the work carrier 110 to a specific level by the controller 150.

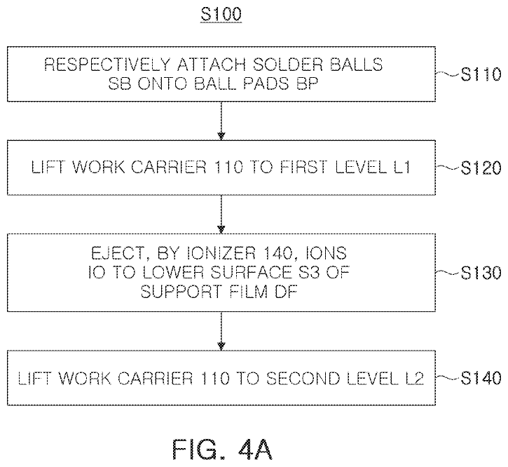

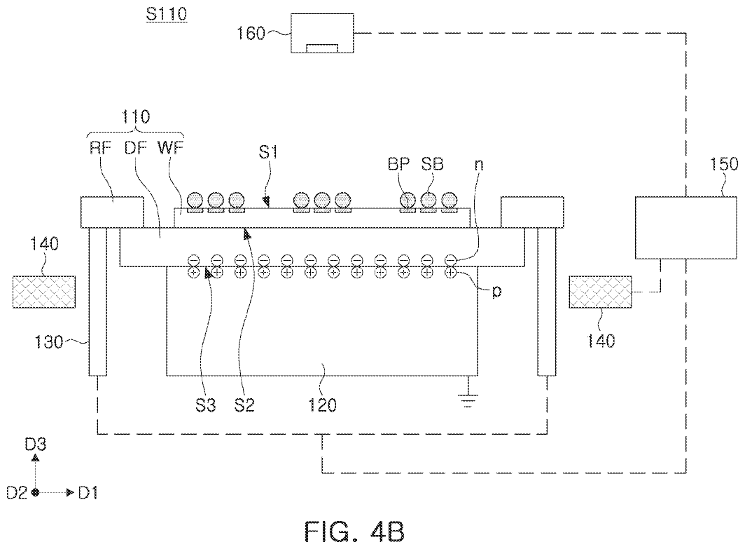

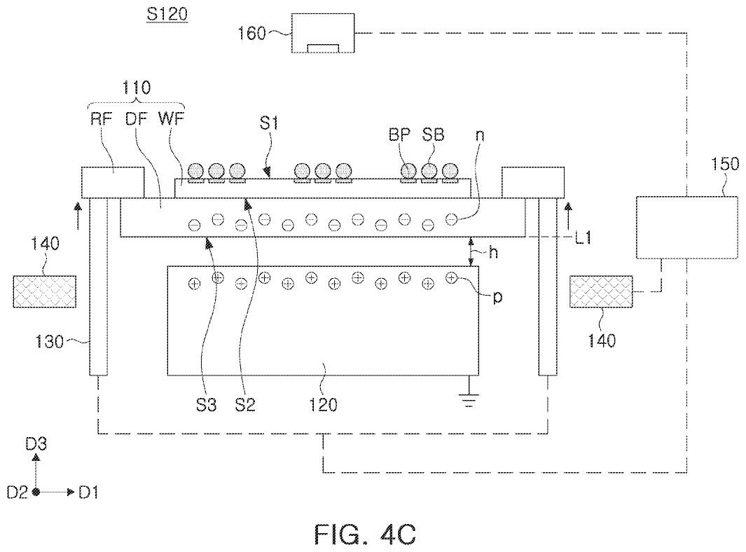

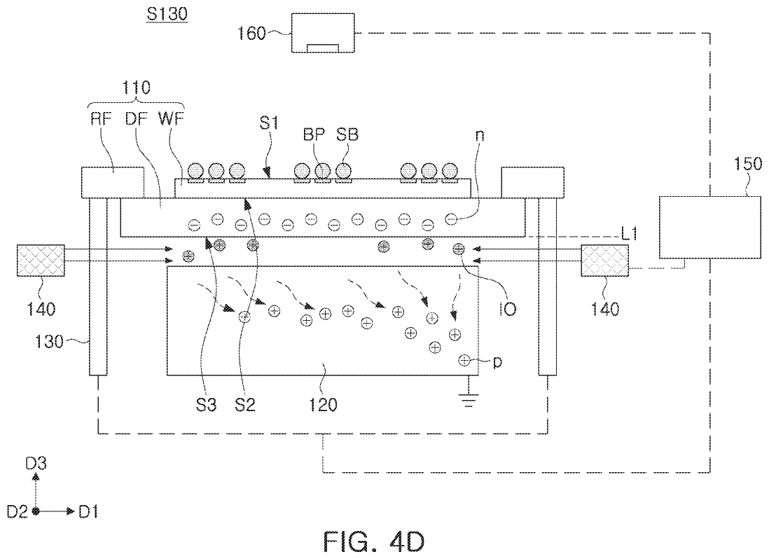

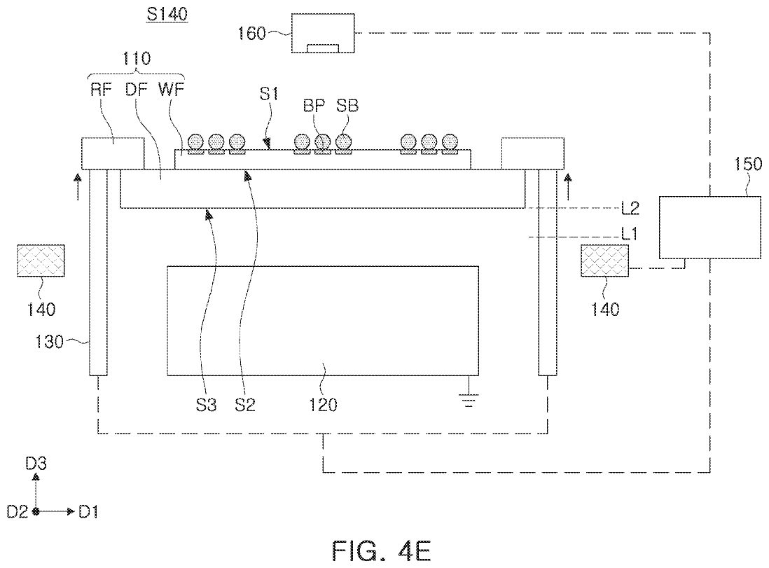

The ionizer 140 may be disposed to be adjacent to the lower surface S3 of the support film DF. The ionizer 40 may be configured to blow ions having a charge opposite to static electricity charged on the support film DF. The ionizer 140 may be operated only in a section in which attractive force between charges charged on the support film DF and the placement table 120 is maintained by the controller 150 (see FIG. 4C).

The controller 150 may be implemented as hardware, firmware, software, or any combination thereof. For example, the controller may include a computing device such as a workstation computer, a desktop computer, a laptop computer, a tablet computer, and the like. The controller may be implemented by a general-purpose computer or application-specific hardware such as a digital signal processor (DSP), a field programmable gate array (FPGA), and an application specific integrated circuit (ASIC).

The controller 150 may control the lifting pins 130 and the ionizer 140. The controller 150 may control the lifting pins 130 such that the support film DF (or work carrier 110) is moved from a support surface of the placement table 120 to a first level and a second level in a stepwise manner. The first level and the second level may be preset to heights that meet conditions to be described below.

The first level may be a position at which a first surface voltage of the first surface S1 of the substrate WF is lower than a second surface voltage of the lower surface S3 of the support film DF. The first surface voltage may be about ±150 V or less, or about ±100 V or less, and the second surface voltage may be about ±500 V or more. For example, the first surface voltage may be within a range from about ±80 V to about ±100 V, but the present inventive concept is not necessarily limited thereto. That is, the first level and the first surface voltage may be set depending on various conditions, such as materials of the placement table 120 and the support film DF, a material of the substrate WF, and pitches of the solder balls SB.

The controller 150 may control the ionizer 140 to eject ions after the support film DF is positioned on the first level or while the support film DF is lifted to the first level such that static electricity charged on the support film DF is removed in a section from the support surface of the placement table 120 to the first level. Attractive force between charges charged on the support film DF and the placement table 120 may be maintained at the first level, thereby suppressing a movement of charges charged on the support film DF and a shift of the solder balls SB. In addition, the lower surface S3 of the support film DF and the support surface of the placement table 120 may be separated from each other by a predetermined distance at the first level, thereby increasing static electricity elimination efficiency of the ionizer 140 for the lower surface S3 of the support film DF.

The controller 150 may control the lifting pins 130 to lift the support film DF from the first level to the second level after the operation of the ionizer 140 is terminated. The second level may be a position at which the work carrier 110 is unloaded for a subsequent process. The second level may be set to a height at which the work carrier 110 may be stably picked up by a robot arm or the like. At the second level, the first surface voltage of the substrate WF may be about ±100 V or less.

The carrier dechucking system S100 according to some implementations may further include a surface potential sensor 160 for measuring the first surface voltage of the substrate WF. The surface potential sensor 160 may be separated from the first surface S1 of the substrate WF to maintain an appropriate measurement distance. The surface potential sensor 160 may include an ultrasonic sensor for controlling a measurement distance. The surface potential sensor 160 may measure static electricity charged on the first surface S1 of the substrate WF. In a state in which the support film DF and the placement table 120 are in contact with each other, the first surface voltage of the substrate WF may be measured as about 0 V. Here, 0 V may be based on a concept including a prime number close to 0, and may define a small quantity of charges being moved to the first surface S1 of the substrate WF by attractive force between charges on the support film DF and the placement base 120. In some implementations, the controller 150 may set and correct the height of the first level using the first surface voltage measured by the surface potential sensor 160.

FIG. 4A is a flowchart illustrating a dechucking process performed by a carrier dechucking system S100 according to some implementations, and FIGS. 4B to 4E are diagrams sequentially illustrating a carrier dechucking process according to some implementations.

Referring to FIGS. 4A and 4B, solder balls SB may be attached to a work carrier 110 mounted on a placement table 120 (S110). The solder balls SB may be aligned on ball pads BP of a substrate WF. The solder balls SB may maintain alignment positions thereof by a flux applied on the ball pads BP. The work carrier 110 may be adsorbed and fixed by vacuum pressure applied to a support surface of the placement table 120. The work carrier 110 may be in contact with the placement table 120 through a lower surface S3 of a support film DF. The support film DF and the placement table 120 may be charged depending on a charging order of materials included therein. For example, the support film DF may be charged with a negative charge (n), and the placement table 20 may be charged with a positive charge (p). FIG. 4A illustrates the lifting pins 130 are in contact with a ring frame RF of the work carrier 110, but the lifting pins 130 may be separated from the work carrier 110 and may be in standby. The lifting pins 130 may lift the work carrier 110 in a stepwise manner according to a driving signal of a controller 150.

Referring to FIGS. 4A and 4C, the work carrier 110 may be lifted from the placement table 120 to a first level L1 (S120). The work carrier 110 may be lifted to the first level L1 by the lifting pins 130. The controller 150 may control the operation of the lifting pins 130 such that a position of the work carrier 110 is maintained at the first level L1. In some implementations, the controller 150 may determine a height of the first level L1 using a first surface voltage measured by a surface potential sensor 160, but the present inventive concept is not limited thereto. The controller 150 may lift the work carrier 110 to a preset height of the first level L1.

At the first level L1, attractive force between the negative charge (n) charged on the support film DF and the positive charge (p) charged on the placement table 120 can be maintained. Accordingly, the negative charge (n) charged on the support film DF may not move to a first surface S1 of the substrate WF. At the first level, a first surface voltage of the substrate WF may be within a range of a reference voltage (for example, about ±100 V or less). For example, the first surface voltage may be within a range from about ±80 V to about ±100 V, but the present inventive concept is not necessarily limited thereto.

At the first level L1, a separation distance (h) between the lower surface S3 of the support film DF and the support surface of the placement table 120 may range from 1 mm to 20 mm, 2 mm to 15 mm, and 3 mm to 10 mm, but the present inventive concept is not limited thereto. The separation distance (h) may be set depending on various conditions, such as materials of the placement table 120 and the support film DF, a material of the substrate WF, and pitches of the solder balls SB.

Referring to FIGS. 4A and 4D, ions IO may be ejected to the lower surface S3 of the support film DF (S130). The ions IO may be ejected together with air AR by the ionizer 140. In some implementations, the ionizer 140 may eject the ions IO after the work carrier 110 is moved to the first level L1. However, in some implementations, the ionizer 140 may eject the ions IO while the work carrier 110 is lifted from the support surface of the placement table 120 to the first level L1.

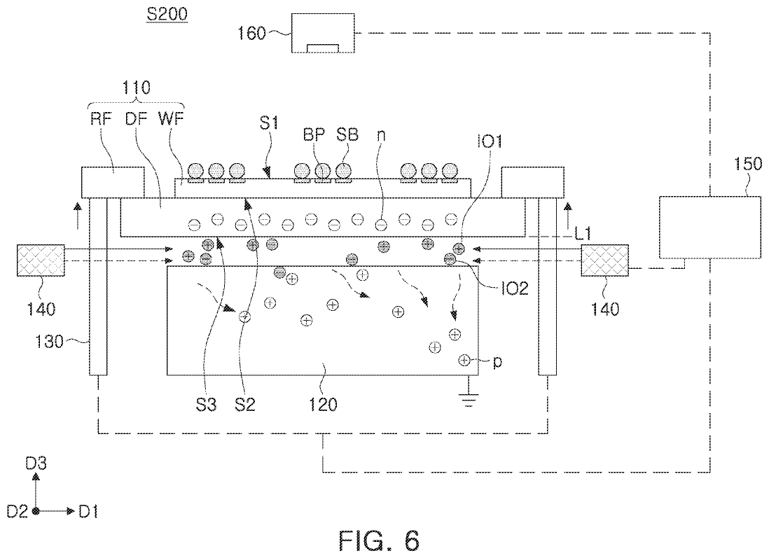

The ionizer 140 may be configured to eject only one of a positive ion and a negative ion having a charge opposite to static electricity charged on the lower surface S3 of the support film DF, but the present inventive concept is not limited thereto. The ions IO may remove charges (for example, negative charges (n)) charged on the lower surface S3 of the support film DF. The separation distance (h) secured between the placement table 120 and the lower surface S3 of the support film DF may improve static electricity elimination efficiency by the ionizer 140. Charges (for example, positive charges (p)) charged on the placement table 120 may be removed through a ground path connected to the placement table 120. In some implementations, the ionizer 140 may be configured to alternately eject a positive ion and a negative ion. In this case, charges (for example, positive charges (p)) charged on the placement table 120 may be removed by the ions ejected by the ionizer 140 (see FIG. 6).

Referring to FIGS. 4A and 4E, the work carrier 110 may be lifted from the placement table 120 to a second level L2 (S140). The work carrier 110 may be re-lifted by lifting pins 130 after the operation of the ionizer 140 is stopped. The second level L2 may be set to a height at which the work carrier 110 may be stably picked up by a robot arm or the like. While the work carrier 110 is lifted from the first level L1 to the second level L2, a first surface voltage of the substrate WF may be within a range of a reference voltage (for example, about ±100 V or less). After the work carrier 110 is positioned on the second level L2, the work carrier 110 may be unloaded by an external device (for example, a robot arm).

In some implementations, the controller 150 may also control the lifting pins 130 such that the work carrier 110 is maintained at a level between the first level L1 and the second level L2 using the first surface voltage measured by the surface potential sensor 160. For example, when the first surface voltage rises to be greater than the reference voltage while the work carrier 110 is lifted from the first level L1 to the second level L2 after the operation of the ionizer 140 is terminated (for example, the first surface voltage is greater than about ±100 V), the controller 150 may control the lifting pins 130 to stop lifting of the work carrier 110, and may reoperate the ionizer 140.

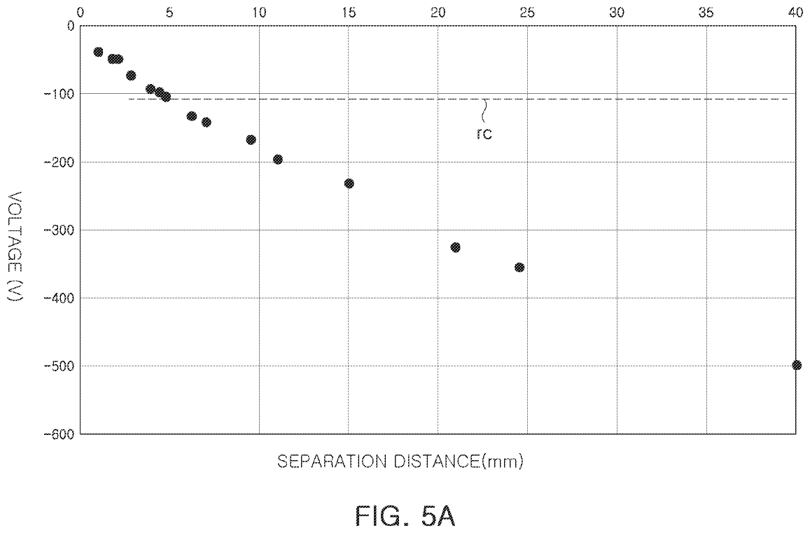

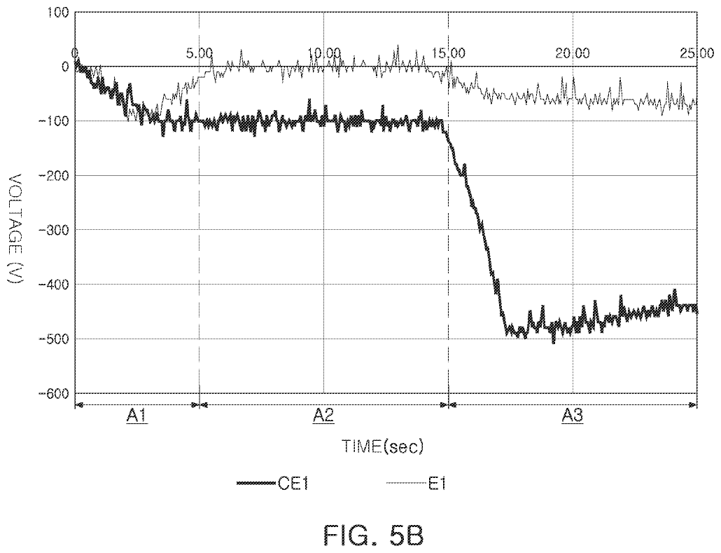

Thus, the carrier dechucking system S100 according to some implementations may effectively suppress a movement of charges on the support film DF and a shift of the solder balls SB by removing static electricity charged on the support film Df while maintaining the work carrier 110 at a separation distance (h) (or first level L1) at which attractive force acts between charges charged on the support film DF and the placement table 120. Hereinafter, a static electricity elimination effect occurring when the ionizer 140 is operated while maintaining a predetermined separation distance (h) will be described with reference to FIGS. 5A and 5B.

FIG. 5A is a graph illustrating a surface voltage of a substrate WF with respect to a separation distance (h) between a work carrier 110 and a placement table 120 according to some implementations, and FIG. 5B is a graph illustrating a difference in surface voltages of a substrate WF depending on whether an ionizer 140 is operated when a work carrier is lifted in a stepwise manner according to some implementations.

Referring to FIG. 5A, the surface voltage of the substrate WF caused by peeling electrification may increase as a separation distance (h) between the work carrier 110 and the placement table 120 increases. When a reference voltage (rc) at which a shift of the solder balls SB is suppressed is set to about −100 V, the separation distance (h) between the work carrier 110 and the placement table 120 may be determined to be about 5 mm. In some implementations, when the reference voltage is set to be less than about −100 V or greater than −100 V, the separation distance (h) between the work carrier 110 and the placement table 120 may be determined to be less than about 5 mm or greater than about 5 mm. FIG. 5A illustrates a change in surface voltage of the substrate WF caused by peeling electrification, when the support film DF includes polyethylene and the placement table 120 includes aluminum.

Referring to FIG. 5B, a voltage graph E1 of a first example and a voltage graph CE1 of a first comparative example are illustrated. Region A1 may be a section in which the work carrier 110 is lifted to a first level L1. Region A2 may be a section in which the work carrier 110 is maintained at the first level L1. Region A3 may be a section in which the work carrier 110 is lifted to a second level L2. The voltage graph E1 of the first example illustrates a change in surface voltage of the substrate WF when the ionizer 140 is operated in region A2. The voltage graph CE1 of the first comparative example illustrates a change in surface voltage of the substrate WF when the ionizer 140 is not operated in region A2. In the voltage graph E1 of the first example, a voltage may be reduced to be close to 0 V in region A2, and may be maintained to be less than a reference voltage (about −100 V) in region A3. Conversely, in the voltage graph CE1 of the first comparative example, a voltage may be maintained to be close to the reference voltage (about −100 V) in region A2, and may be increased to be greater than the reference voltage (about −100 V) in region A3.

FIG. 6 is a schematic diagram illustrating a carrier dechucking system S200 according to some implementations.

Referring to FIG. 6, the carrier dechucking system S200 according to some implementations may have features the same as or similar to those described with reference to FIGS. 1 to 5B, except that the ionizer 140 is configured to eject both a positive ion IO1 and a negative ion IO2.

The ionizer 140 may be configured to alternately or simultaneously eject the positive ion IO1 and the negative ion IO2. The positive ion IO1 and the negative ion IO2 ejected from the ionizer 140 may remove static electricity charged on a support film DF and a placement table 120. For example, when the support film DF is negatively charged depending on a charging order, negative charges (n), adjacent to a lower surface S3 of the support film DF, may be neutralized by the positive ion IO1 ejected from the ionizer 140. In addition, when the placement table 120 is positively charged, positive charges (p), adjacent to the lower surface S3 of the support film DF, may be neutralized by the negative ion IO2 ejected from the ionizer 140.

FIG. 7A is a schematic diagram illustrating a carrier dechucking system S300 according to some implementations, and FIG. 7B is a graph illustrating a difference in surface voltages of a substrate depending on whether lifting pins 130 are grounded.

Referring to FIG. 7A, the carrier dechucking system S300 according to some implementations may have features the same as or similar to those described with reference to FIGS. 1 to 6, except that at least some lifting pins 130 are grounded.

The at least some lifting pins 130 that are grounded may be in contact with one side of a support film DF. For example, the at least some lifting pins 130 may be configured to press a lower surface S3 of the support film DF. Static electricity charged on the support film DF may be removed along a ground path of the lifting pins 130. For example, negative charges (n) charged on the support film DF may be neutralized by ions IO ejected from the ionizer 140 or may be removed along the ground path of the lifting pins 130. Thus, the static electricity charged on the support film DF may be more effectively removed by forming a ground path connected to the support film DF.

Referring to FIG. 7B, a voltage graph E2 of a second example and a voltage graph CE2 of a second comparative example are shown. Region B1 may be a section in which a work carrier 110 is in contact with a support surface of a placement table 120. Region B2 may be a section in which vacuum pressure of the placement table 120 is removed and a work carrier 110 is lifted to a second level L2 via a first level L1. In the voltage graph E2 of the second example, a voltage may be maintained to be close to about −200 V in region B2. Conversely, in the voltage graph CE2 of the second comparative example, a voltage may be increased to about −500 V in region B2.

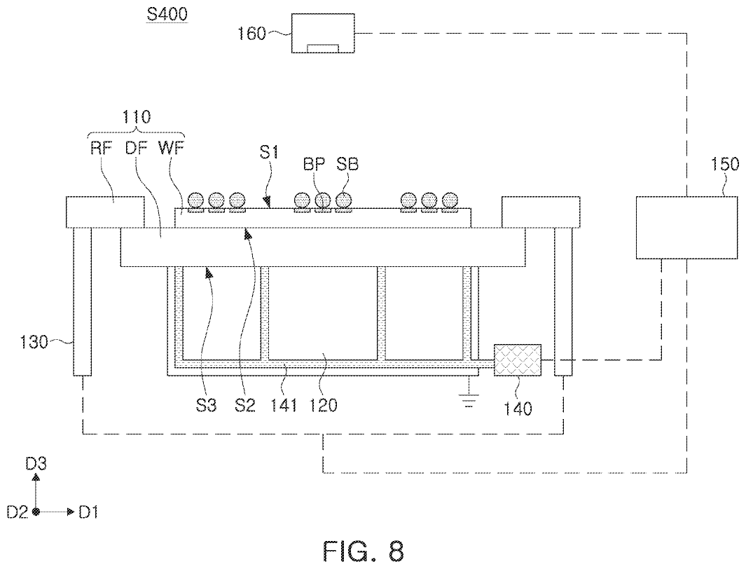

FIG. 8 is a schematic diagram illustrating a carrier dechucking system S400 according to some implementations.

Referring to FIG. 8, the carrier dechucking system S400 according to some implementations may have features the same as or similar to those described with reference to FIGS. 1 to 7B, except that an ion ejection path 141, extending toward a lower surface S3 of a support film DF, is included.

The ionizer 140 may be configured to eject ions through an ion ejecting path 141, passing through an interior of a placement table 120 and extending to a support surface on which the lower surface S3 of the support film DF is mounted. The ionizer 140 may eject ions, (a positive ion and/or a negative ion) generated therein through the ion ejection path 141, to the outside. The ions (a positive ion and/or a negative ion) may be ejected between a support surface of the placement table 120 and the lower surface S3 of the support film DF, such that ions, having a charge opposite to that of the placement table 120, may more effectively remove charges charged on the support film DF by repulsive force.

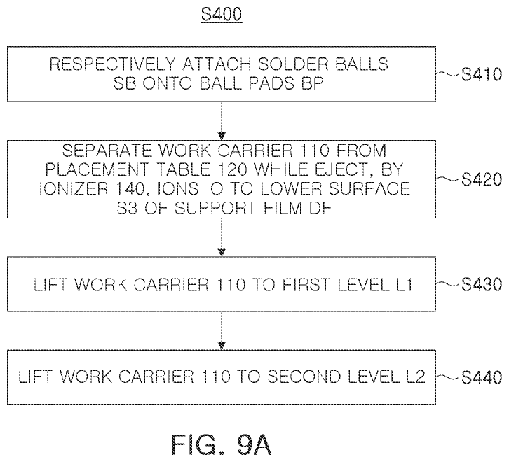

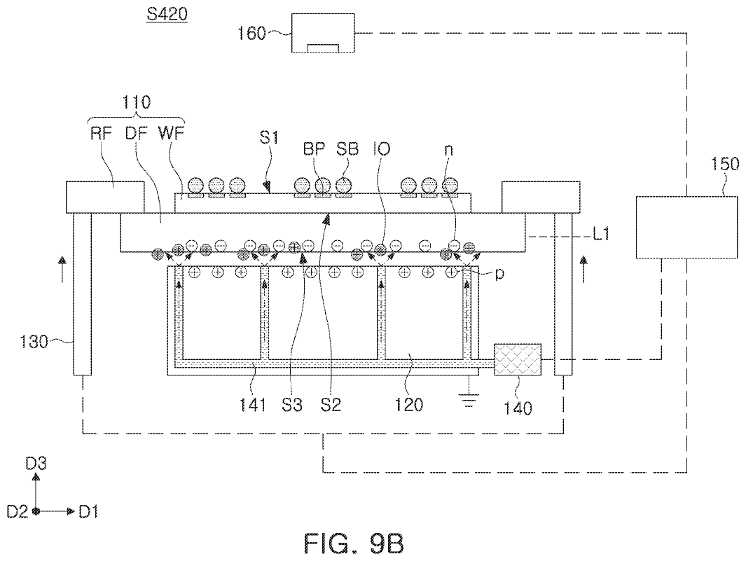

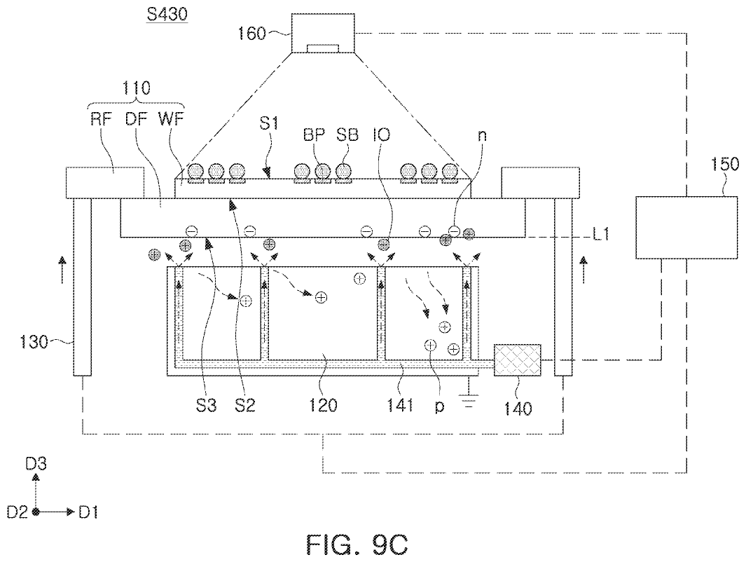

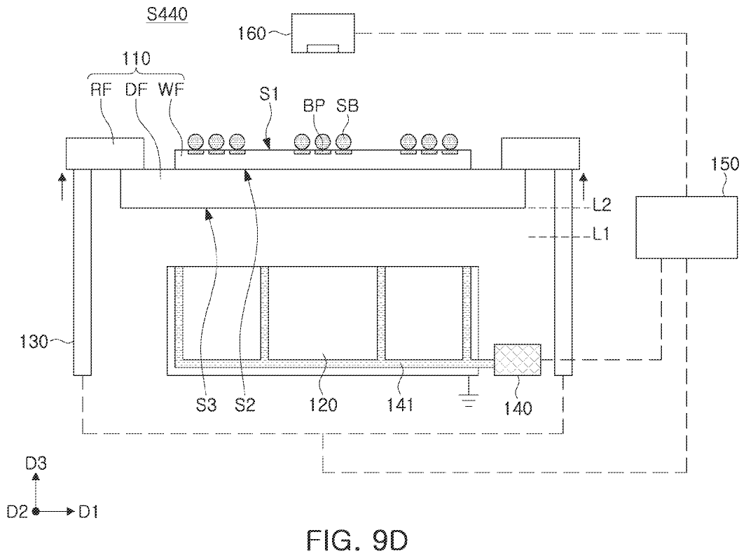

FIG. 9A is a flowchart illustrating a dechucking process performed by a carrier dechucking system S400 according to some implementations, and FIGS. 9B to 9D are diagrams sequentially illustrating a carrier dechucking process according to some implementations.

Referring to FIGS. 9A and 9B, while a substrate WF to which solder balls SB are attached is lifted to a first level L1, ions IO may be ejected to a lower surface S3 of a support film DF (S410 and S420). A controller 150 may operate an ionizer 140 and lifting pins 130 after vacuum pressure of the placement table 120 is removed. The ionizer 140 may eject ions IO (for example, a positive ion) having a charge opposite to static electricity (for example, a negative charge (n)) charged on the support film DF. For example, the ionizer 140 may eject a positive ion having a charge opposite to the negative charge (n) charged on the support film DF. Accordingly, some of negative charges (n) charged on the support film DF may be removed by the ions IO before the work carrier 110 reaches the first level L1. The ions IO may be directly ejected to the lower surface S3 of the support film DF through an ion ejection path 141. However, a method of ejecting the ions IO through the ion ejection path 141 is not necessarily performed simultaneously with lifting of the work carrier 110. For example, the ionizer 140 may eject the ions IO through the ion ejection path 141 after the work carrier 110 reaches the first level L1 (see FIGS. 4C and 4D).

Referring to FIGS. 9A and 9C, the work carrier 110 may be lifted from the placement table 120 to the first level L1 (S430). The controller 150 may control the operation of the lift pins 130 so that a position of the work carrier 110 is maintained at the first level L1. In some implementations, the controller 150 may determine a height of the first level L1 using a first surface voltage measured by a surface potential sensor 160, but the present inventive concept is not limited thereto. The controller 150 may lift the work carrier 110 to a preset height of a first level L1.

In a state in which the work carrier 110 is positioned on the first level L1, attractive force between remaining negative charges (n) charged on the support film DF and remaining positive charges (p) charged on the placement table 120 may be maintained. At the first level, a first surface voltage of the substrate WF may be within a range of a reference voltage (for example, about ±100 V or less). For example, the first surface voltage may be within a range from about ±80 V to about ±100 V, but the present inventive concept is not necessarily limited thereto. The ionizer 140 may additionally eject the ions IO to remove the remaining negative charges (n) and the remaining positive charges (p). For example, the ionizer 140 may eject both a positive ion and a negative ion in a state in which the work carrier 110 is positioned on the first level L1 (see FIG. 6).

Referring to FIGS. 9A and 9D, the work carrier 110 may be lifted from the placement table 120 to a second level L2 (S440). The work carrier 110 may be re-lifted by the lifting pins 130 after the operation of the ionizer 140 is stopped. While the work carrier 110 is lifted from the first level L1 to the second level L2, the first surface voltage of the substrate WF may be within the range of the reference voltage (for example, about ±100 V or less). After the work carrier 110 is positioned on the second level L2, the work carrier 110 may be unloaded by an external device (for example, a robot arm).

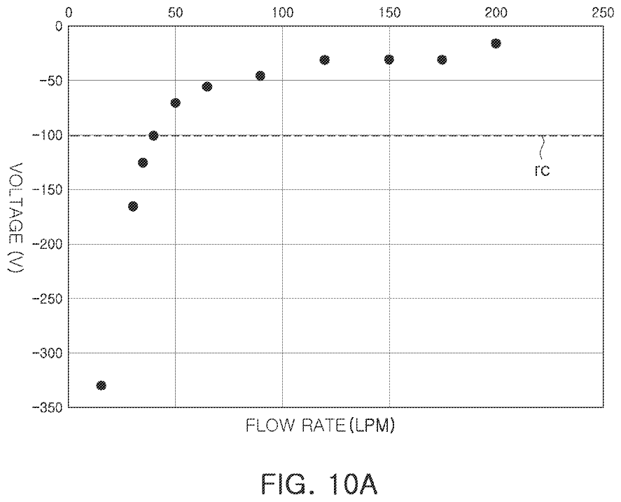

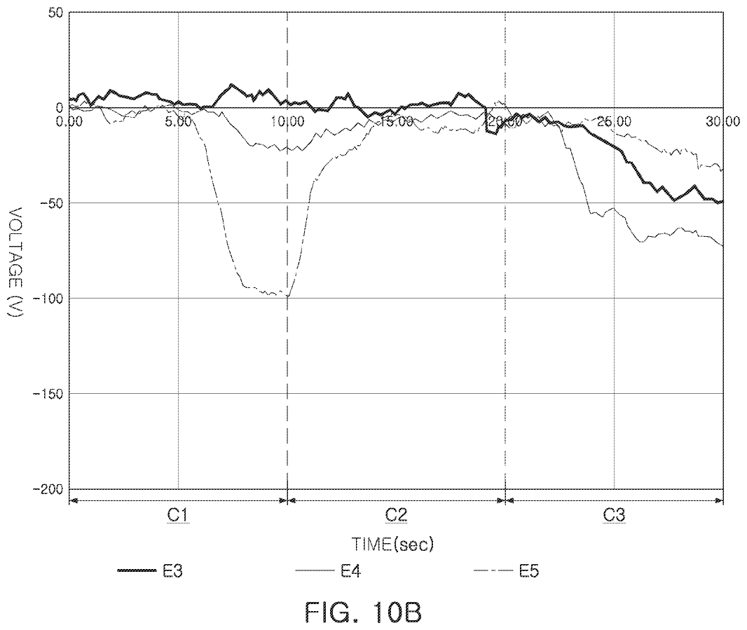

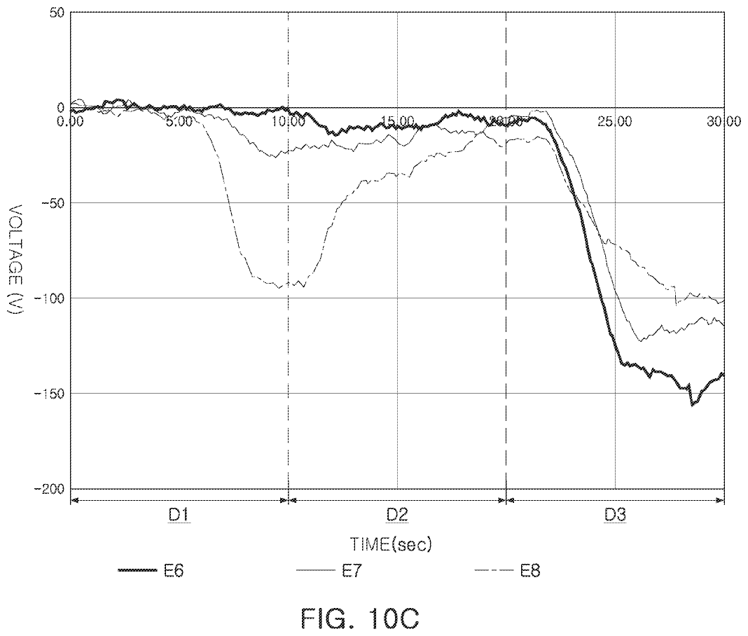

Thus, the carrier dechucking system S400 according to some implementations may more effectively remove static electricity by directly ejecting the ions IO to the lower surface S3 of the support film DF through the ion ejection path 141. Hereinafter, a static electricity removal effect according to a flow rate of the ionizer 140 will be described with reference to FIGS. 10A to 10C.

FIG. 10A is a graph illustrating a surface voltage of a substrate with respect to a flow rate of an ionizer, and FIGS. 10B and 10C are graphs illustrating a difference in surface voltages of a substrate according to a difference in a first level, when a work carrier is lifted in a stepwise manner under the condition that an ionizer has the same flow rate.

Referring to FIG. 10A, a surface voltage of a substrate WF may decrease as a flow rate of an ionizer 140 increases. When the flow rate of the ionizer 140 is about 40 litres per minute (LPM) or more, the surface voltage of the substrate WF may be reduced to be less than a reference voltage (rc) (about −100 V). FIG. 10A illustrates a difference in surface voltages of the substrate WF when ions IO are ejected at a specific flow rate through an ion ejection path 141 while a work carrier 110 is lifted to a second level L2. FIGS. 10B and 10C illustrate a change in surface voltage of the substrate WF when a separation distance of the work carrier 110 is differently adjusted at a first level L1 in a state in which the flow rate of the ionizer 140 is fixed at 90 LPM and 50 LPM, respectively.

Referring to FIG. 10B, a voltage graph E3 of a third example, a voltage graph E4 of a fourth example, and a voltage graph E5 of a fifth example are illustrated. Region C1 may be a section in which the work carrier 110 is lifted to the first level L1. Region C2 may be a section in which the work carrier 110 is maintained at the first level L1 and the ionizer 140 is operated. Region C3 may be a section in which the work carrier 110 is lifted to the second level L2.

The voltage graph E3 of the third example illustrates a change in surface voltage of the substrate WF when a separation distance between the work carrier 110 and a placement table 120 is about 2 mm at the first level L1. The voltage graph E4 of the fourth example illustrates a change in surface voltage of the substrate WF when the separation distance between the work carrier 110 and the placement table 120 is about 5 mm at the first level L1. The voltage graph E5 of the fifth example illustrates a change in surface voltage of the substrate WF when the separation distance between the work carrier 110 and the placement table 120 is about 10 mm at the first level L1.

In the voltage graph E3 of the third example, a voltage at the first level L1 may be about −14 V, and a voltage at the second level L2 may be about −51 V. In the voltage graph E4 of the fourth example, a voltage at the first level L1 may be about −23.5 V, and a voltage at the second level L2 may be about −73 V. In the voltage graph E5 of the fifth example, a voltage at the first level L1 may be about −99 V, and a voltage at the second level L2 may be about −34 V. As a result, in the case that the ionizer 140 has a flow rate of about 90 LPM, it may be confirmed that a static electricity removal effect is most significant when the separation distance is about 2 mm at the first level L1.

Referring to FIG. 10C, a voltage graph E6 of a sixth example, a voltage graph E7 of a seventh example, and a voltage graph E8 of an eighth example are illustrated. Region D1 region may be a section in which the work carrier 110 is lifted to the first level L1. Region D2 may be a section in which the work carrier 110 is maintained at the first level L1 and the ionizer 140 is operated. Region D3 may be a section in which the work carrier 110 is lifted to the second level L2.

The voltage graph E6 of the sixth example illustrates a change in surface voltage of the substrate WF when the separation distance between the work carrier 110 and the placement table 120 is about 2 mm at the first level L1. The voltage graph E7 of the seventh example illustrates a change in surface voltage of the substrate WF when the separation distance between the work carrier 110 and the placement table 120 is about 5 mm at the first level L1. The voltage graph E8 of the eighth example illustrates a change in surface voltage of the substrate WF when the separation distance between the work carrier 110 and the placement table 120 is about 10 mm at the first level L1.

In the voltage graph E6 of the sixth example, a voltage at the first level L1 may be about −14.5 V, and a voltage at the second level L2 may be about −156.5 V. In the voltage graph E7 of the seventh example, a voltage at the first level L1 may be about −27 V, and a voltage at the second level L2 may be about −123 V. In the voltage graph E8 of the eighth example, a voltage at the first level L1 may be about −94.5 V, and a voltage at the second level L2 may be about −104.5 V. As a result, when the ionizer 140 has a flow rate of about 50 LPM, it may be confirmed that a static electricity elimination effect is most excellent when the separation distance is about 10 mm at the first level L1.

According to some implementations of the present inventive concept, a carrier dechucking system and a carrier dechucking method using the same may remove static electricity while maintaining a predetermined separation distance between a substrate to which solder balls are temporarily attached and a placement table, when the substrate is separated from the placement table, thereby restricting a decrease in reliability caused by static electricity.

While this specification contains many specific implementation details, these should not be construed as limitations on the scope of any invention or on the scope of what may be claimed, but rather as descriptions of features that may be specific to particular embodiments of particular inventions. Certain features that are described in this specification in the context of separate embodiments can also be implemented in combination in a single embodiment. Conversely, various features that are described in the context of a single embodiment can also be implemented in multiple embodiments separately or in any suitable subcombination. Moreover, although features may be described above as acting in certain combinations and even initially be claimed as such, one or more features from a claimed combination can in some cases be excised from the combination, and the claimed combination may be directed to a subcombination or variation of a subcombination.

While implementations have been illustrated and described above, it will be apparent to those skilled in the art that modifications and variations could be made without departing from the scope of the present inventive concept as defined by the appended claims.

1. A carrier dechucking system comprising:
a work carrier including:
a substrate having a first surface to which solder balls are attached and a second surface opposite to the first surface,
a support film attached to the second surface of the substrate, and
a ring frame surrounding the substrate on an outer periphery of the support film;
a placement table configured to place the work carrier, the placement table having a support surface configured to maintain a lower surface of the support film;
lifting pins configured to move the work carrier in a direction perpendicular to the support surface of the placement table;
at least one ionizer configured to eject ions to the lower surface of the support film; and
a controller configured to control the lifting pins to move the work carrier from the support surface to a first level and a second level in a stepwise manner, and to control the at least one ionizer to remove static electricity charged on the support film at a section that is defined from the support surface to the first level,
wherein the first level corresponds to a position at which a first surface voltage of the first surface of the substrate is lower than a second surface voltage of the lower surface of the support film.

2. The carrier dechucking system of claim 1, wherein the first surface voltage is about ±100 V or less at the first level.

3. The carrier dechucking system of claim 2, wherein the second surface voltage is about ±500 V or more at the first level.

4. The carrier dechucking system of claim 1, wherein the second level corresponds to a position at which the work carrier is unloaded for a subsequent process.

5. The carrier dechucking system of claim 1, wherein the first surface voltage is about ±100 V or less at the second level.

6. The carrier dechucking system of claim 1, wherein the at least one ionizer is configured to eject one of a positive ion or a negative ion, the ejected one of the positive ion or the negative ion having a charge opposite to static electricity charged on the lower surface of the support film.

7. The carrier dechucking system of claim 1, wherein the at least one ionizer is configured to alternately eject a positive ion and a negative ion.

8. The carrier dechucking system of claim 1, wherein
at least some of the lifting pins are grounded, and
the at least some of the lifting pins are configured to press the lower surface of the support film.

9. The carrier dechucking system of claim 1, wherein the at least one ionizer is disposed to be adjacent to the lower surface of the support film.

10. The carrier dechucking system of claim 1, wherein the at least one ionizer includes an ion ejection path passing through an interior of the placement table and extending to the support surface.

11. The carrier dechucking system of claim 1, wherein the controller is configured to control the at least one ionizer to eject the ions after the work carrier is moved from the support surface to the first level.

12. The carrier dechucking system of claim 1, wherein the controller is configured to control the at least one ionizer to eject the ions while the work carrier is moved from the support surface to the first level.

13. The carrier dechucking system of claim 1, further comprising:
a surface potential sensor configured to measure the first surface voltage of the substrate.

14. The carrier dechucking system of claim 13, wherein the controller is configured to determine the first level using the first surface voltage measured by the surface potential sensor.

15. The carrier dechucking system of claim 13, wherein when the first surface voltage, measured by the surface potential sensor, is greater than about ±100 V at a level between the first level and the second level, the controller is configured to control the lifting pins such that the work carrier is maintained at the level between the first level and the second level.

16. A carrier dechucking system comprising:
a support film configured to mount a substrate, the substrate configured to attach solder balls;
a placement table having a support surface configured to maintain the support film;
lifting pins configured to move the support film in a direction perpendicular to the support surface of the placement table;
at least one ionizer configured to eject ions to the support film; and
a controller configured to control the lifting pins to lift the support film from the support surface to a first level and a second level in a stepwise manner, and to control the at least one ionizer to eject the ions based on the support film being positioned on the first level.

17. The carrier dechucking system of claim 16, wherein a surface voltage of an upper surface of the substrate is from about ±80 V to about ±100 V at the first level.

18. The carrier dechucking system of claim 16, wherein the controller is configured to control the lifting pins to lift the support film from the first level to the second level after ejection of the ions is terminated.

19. A carrier dechucking system comprising:
a support film configured to mount a substrate to which solder balls are attached;
a placement table having a support surface configured to maintain the support film;
lifting pins configured to move the support film in a direction perpendicular to the support surface of the placement table;
at least one ionizer configured to eject ions to a lower surface of the support film through an ion ejection path passing through an interior of the placement table and extending to the support surface; and
a controller configured to control the lifting pins to lift the support film from the support surface to a first level and a second level in a stepwise manner.

20. The carrier dechucking system of claim 19, wherein the controller is configured to control the at least one ionizer to eject the ions while the support film is lifted from the support surface to the first level.

21.-25. (canceled)
